(19) United States
(12) Patent Application Publication
(10) Pub. No.: US 2011/0235360 A1
(43) Pub. Date: Sep. 29, 2011

(54) LIGHT SOURCE DEVICE FOR SUPPLYING LIGHT TO FIBER OPTIC ILLUMINATION SYSTEM

(75) Inventors: Haruo ITOH, Kanagawa (JP); Kunio ANDO, Saitama (JP)

(73) Assignees: MEDIA TECHNOLOGY CO., LTD., Yokohama-shi (JP); AI SYSTEMS INC., Saitama-shi (JP)

(21) Appl. No.: 12/852,886

(22) Filed: Aug. 9, 2010

(30) Foreign Application Priority Data
Mar. 29, 2010 (JP) 2010-074108

(51) Int. Cl. H01L 33/00

(52) U.S. Cl. 362/555

(57) ABSTRACT

A light source device for a fiber optic illumination system comprises a solid-state light emitting element having an emission surface shaped in quadrate, a light collection lens system with a positive power comprising at least a plano-convex lens, and a reflection member having a cylindrical reflection surface therein, all of which are arranged in this order coaxially with one another along a principal axis passing a center of the light emitting element, wherein the plano-convex lens is placed with a plane surface thereof directly facing and located at a space distance apart from the emission surface so as to form a virtual image of the emission surface.

### BACKGROUND OF THE INVENTION

This application claims the priority of Japanese Patent Application No. 2010-074108 filed on Mar. 29, 2010 which is incorporated therein by reference.

1. Field of the Invention

The present invention relates to a light source device capable of efficiently supplying light from a solid-state light emitting element such as a light emitting diode to a fiber optic illumination system which is used in itself to provide illumination for observation of a narrow space or is incorporated as a light guide means for illuminating a body cavity in an endoscope.

2. Description of Related Art

Illumination systems which are widely used in themselves for illumination of relatively restricted, narrow spaces or are incorporated in endoscopes are provided with light guide means comprising an optical fiber bundle. A light source device for such a fiber optic illumination system including an optical fiber bundle comprises a light source and a collective lens system for collecting light from the light source and supplying it to the light guide means. It has been quite usual to incorporate a xenon lamp or a halogen lamp as a light source in the light source device. As a consequence of reduced size and notable performance improvement of recent solid-state light emitting elements, a light emitting diode (LED) typical of such a solid-state light emitting element has became widely used as a light source. In the following description, the term “light emitting diode (LED)” is used to typify solid-state light emitting elements.

In many light source devices, as described in Unexamined Japanese Patent Publications 2003-135380 and 2004-275277, a convex lens system having a positive power is employed as the collective lens system to converge light from an emission surface of the light emitting diode in a real imaging system.

The light emitting diode as a light source has a distribution of luminous intensity in a wide angular range as shown in FIG. 1 illustrating a luminous intensity distribution curve of a light emitting diode by way of example. In FIG. 1, the ordinate axis (Y-axis) 101 indicates a relative value of luminous intensity which is taken as 1.0 at a principal axis, i.e. a center axis, of an emission surface of the light emitting diode, and the abscissa axis (X-axis) 102 indicates an angle of emission (which is hereinafter referred to as an emission angle) with the principal axis of the emission surface of the light emitting diode. As apparent from the luminous intensity distribution curve, the light emitting diode has a wide emission angle. The quantity of light that is actually utilized for illumination is only 50% of the available quantity of light when using light in the range of emission angle of 70° (±35° with the principal axis of the emission surface) and, however, 80% of the available light when using light in the range of emission angle of 110° (±55° with the principal axis of the emission surface) or 85% of the available quantity of light when using light in the range of emission angle of 120° (±60° with the principal axis of the emission surface).

Optical fibers forming an optical fiber bundle commonly used as a light guide means of a fiber optic illumination system have a numerical aperture NA of approximately 0.57, i.e. an acceptance angle 2θ of 70°. Also, it is not always popularly practiced, an optical fiber bundle comprising optical fibers having a large numerical aperture of, for instance, 0.87 (an acceptance angle 2θ=120°) has come into practical use as a light guide.

In the case where an illumination system comprises a light emitting diode and a light guide in combination, it is required to cause light emerging from the light emitting diode to enter the light guide as effectively as possible. Considering a bundle of optical fibers having a numerical aperture NA=0.57, i.e. an acceptance angle 2θ=70°, as an example of the light guide, it is desired to incorporate a collective lens system so that light which the light emitting diode emits from its emission surface at a wide emission angle falls within the acceptance angle (70°) of the light guide. At the same time, considering about the light collecting optical system including a convex lens system in a real imaging system, when the light collecting lens system comprises a convex lens 201 having a positive power which forms a real image such as shown by way of example in FIG. 2, the collective lens 201 having a focal length f′ is required to have a distance 4 f′ between conjugate points to form an image of an object at ×1 magnification and a distance 4.5 f′ between conjugate points to form an image of the object at ×2 magnification. When laying an emission surface of the light emitting diode in an object plane, the collective lens 201 is required to have a large aperture in order to collect a divergent bundle of light rays emerging from the emission surface of the light emitting diode at a wide emission angle (which is approximately 120°) on an incident end of the light guide with a high efficiency and, as a necessary consequence, must generally be large in size.

Reference is made to FIGS. 3A and 3B to conceptualize emission of light of a light emitting diode 301 having a square emission surface 302 having a principal axis Xp which is a vertical line at the center Oa of the emission surface 302. In FIG. 3A, based on the concept that the emission surface 302 comprises an aggregation of fine points of light emission (which are hereinafter referred to as emission points), there are schematically shown light rays from emission points at emission angle of 0° and ±60° with respect to the principal axis Xo. In the drawings, an angle marked by a minus sign (−) indicates an emission angle as viewed in a counterclockwise direction and an angle marked by a plus sign (+) in a clockwise direction. As was previously described, when using light rays from the emission surface 302 within an emission angle range between approximately ±60°, it is assured that the coefficient of light utilization is approximately 85% relative to the total quantity of light rays emerging from the light emitting diode. In light of this, the following description is given taking light rays within, for example, an emission angle range of ±60°.

Light emitting diode chips are often placed on the market in quadrate, square or rectangular, shapes. In some instances, there are available packaged arrays of series-connected light emitting diode chips commercially-designated as, for example, a type LE-W-E2A manufactured by OSRAM Opto Semiconductors. In this specification, such an array of light emitting diode chips, aligned in series or grid, is treated as having a single integrated emission surface. Further, there are available white light emitting diode chips, each of which is provided with a fluorescent screen on its emission surface. These emission surface and fluorescent screen are explained as an emission surface in comprehensive definition.

As shown in FIG. 3B, when regarding the emission surface 302 of the light emitting diode 301 as an aggregation of fine light emission points, the emission surface is perceived as a continuous arrangement of virtual annular ring emission surfaces (only one of them is depicted in FIG. 3B) having a regular minimal width Δ and radii r which border on one another. The annular ring emission surface has an emissive area expressed as 2πr·Δ. Therefore, the closer the annular ring emission surface to the periphery (inscribed circle) of the emission surface, the greater its emissive area, and hence the greater the quantity of light to emerge. Such being the case, it is very important for small-sized, efficient collective lens to be capable of collecting light rays from the annular emission surfaces from the center to the periphery without a loss of available light.

As was previously described, if collecting light from the emission surface 302 of the light emitting diode 301 within an emission angle of 120° by the use of a real image type of collective lens system comprising a convex lens system, it is unavoidable for the convex lens system to have a large aperture. Consequently, it is hard to configure an efficient, small-sized light source device although using a reduced size of light emitting diode.

Nothing in the above mentioned Publications teaches a technique for solving the problem of efficient collection of light from a light emitting diode at a large distribution angle by the use of a small size of collective lens system.

It is therefore an object of the present invention to provide a light source device having a simple and small sized collective lens system which is capable of efficiently collecting light emerging from a light emitting diode at a large range of emission angles and, more particularly, efficiently collecting light emerging from a periphery of the light emitting diode.

### SUMMARY OF THE INVENTION

The forgoing objects of the present invention are accomplished by a light source device for an illumination system having a light guide means which comprises a solid-state light emitting element capable of emitting its light from an emission surface, square or rectangle, and having a principal axis at a center thereof, a light collection lens system having a positive power which includes at least a plano-convex lens and is arranged coaxially with the solid-state light emitting element along the principal axis and a reflection member having a cylindrical reflection surface therein which is arranged coaxially with the solid-state light emitting element along the principal axis on a side opposite to the solid-state light emitting element with respect to the light collective lens system. The plano-convex lens is placed with a plane surface thereof directly facing and located at a space distance apart from the emission surface so as to form a virtual image of the emission surface.

The light collection lens, such as a single plano-convex lens having a an approximately hemispherical shape, has a curved surface with a radius of curvature within a range between 1 and 1.5 times a width of an emission surface of a light emitting diode and an axial thickness along its optical axis smaller than the radius of curvature and a diameter, hinging on the radius of curvature and the axial thickness, to which a diameter of a cylindrical reflection member is adjusted approximately equally. The width may be either a long side or a short side according to design intent if the emission surface is rectangle.

Alternatively, the light collection lens system may comprise, in addition to the plano-convex lens, a convex lens having a power smaller than the plano-convex lens. The convex lens is arranged coaxially with and between the plano-convex lens and the reflection member along the principal axis.

According to the present invention, the light source device provides high efficiency collection of light emerging from the light emitting diode while simplified in structure and, in consequence, is utilized for various industrial equipments provided with fiber optic illumination systems as well as endoscopes and microscopes.

### BRIEF DESCRIPTION OF THE DRAWINGS

The foregoing and other objects and features of the present invention will be clearly understood from the following detailed description when reading with reference to the accompanying drawings wherein same or similar parts or structures are denoted by the same reference numerals throughout the drawings, and in which:

FIG. 1 is an illustration showing an intensity distribution of emission of a light emitting diode;

FIG. 2 is a schematic illustration of a real image type of collective lens system;

FIG. 3A is a schematic illustration of emission of a light emitting diode;

FIG. 3B is a conceptional illustration of an emission surface of the light emitting diode;

FIGS. 4A and 4B are schematic illustrations for explaining a basic concept of the present invention;

FIG. 5 is an illustration showing a light source device according a preferred embodiment of the present invention; and

FIG. 6 is an illustration showing a light source device according to an alternative embodiment of the present invention.

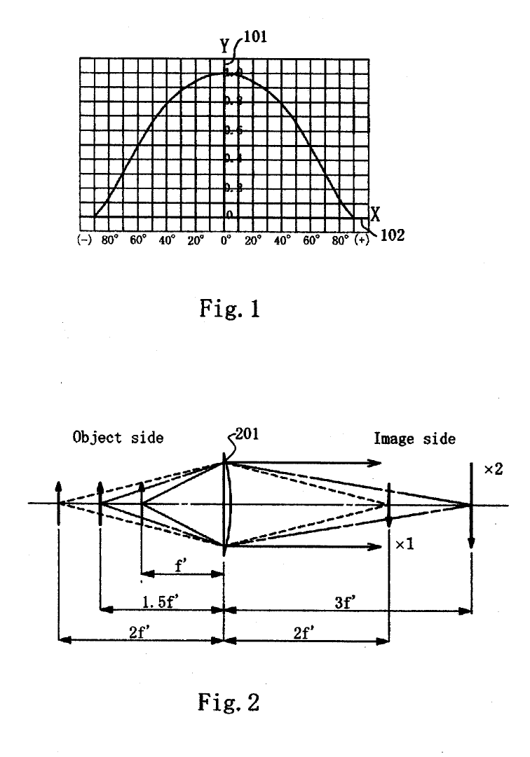

### DETAILED DESCRIPTION OF THE PREFERRED EMBODIMENTS

In the following description, an angle marked with a plus sign (+) indicates an emission angle of light ray with respect to a line perpendicular to an emission surface as viewed in a clockwise direction and an angle marked with a minus sign (−) as viewed in a counterclockwise direction.

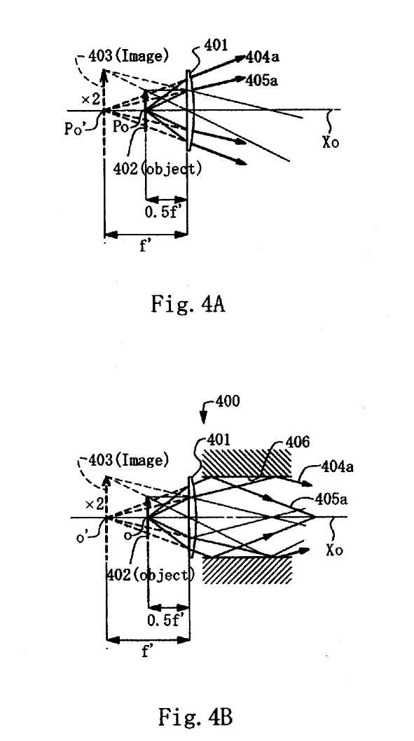

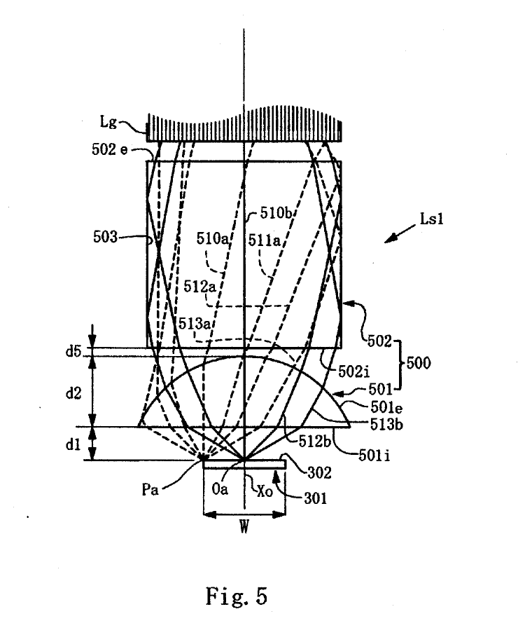

FIG. 4A shows a diagram of image formation by a convex lens (collection lens) 401 having an optical axis Xo when a virtual image 403 of an object 402 (which corresponds to an emission surface of a light emitting diode) is formed at a magnification of ×2. An object point “Po” is virtually focused into an image at an image point “Po′.” In this case, light rays emerging from the object point “Po” are diverged through the collective lens 401 as designated by reference numerals 404a and 405a. As shown in FIG. 4B illustrating a light collection optical system 400 comprising a collective lens (convex lens) 401 and a cylindrical reflection surface 406 located coaxially with and on the exit side of the collective lens 401 along an optical axis Xo, because the light rays 404a and 405a passing through the collective lens 401 are deviated toward the optical axis Xo, it is made possible to provide the cylindrical reflection surface 406 with an aperture as small as an aperture of the collective lens 401. In consequence, the light collection optical system 400 is configured so that light rays passing though the collective lens 401 fall within the aperture of the cylindrical reflection surface 406 and thereby collected at a high efficiency.

In terms of shape of the collective lens 401 to collect light from a light emitting diode, small hemispherical lenses having incident surfaces located close to and covering an emission surface of the light emitting diode are often used. However, because such a small hemispherical lens is hard to fit the above requirement, i.e. to let in all light emanating from a periphery of the light emitting diode at emission angles within approximately ±60° without total reflection by the curved surface, it is undesirable to use the small hemispherical lens in terms of light collecting efficiency.

The light collection lens, such as a single plano-convex lens, for use with a light source device of the present invention is approximately hemispherical and characterized by having a curved surface with a radius of curvature within a range between 1 and 1.5 times a width of an emission surface of a light emitting diode and an axial thickness along its optical axis smaller than the radius of curvature and a diameter, hinging on the radius of curvature and the axial thickness, to which a diameter of a cylindrical reflection member is adjusted approximately equally.

According to this configuration, the light collection optical system 400 causes light rays passing through the collective lens 401 to mix evenly through total reflection by the cylindrical reflection surface 406, so as thereby to provide even illumination.

The cylindrical reflection surface 406 may be provided in the form of an inner reflective wall of a hollow cylindrical member or alternatively in the form a transparent solid cylindrical member, such as a transparent glass cylinder, capable of causing internal total reflection.

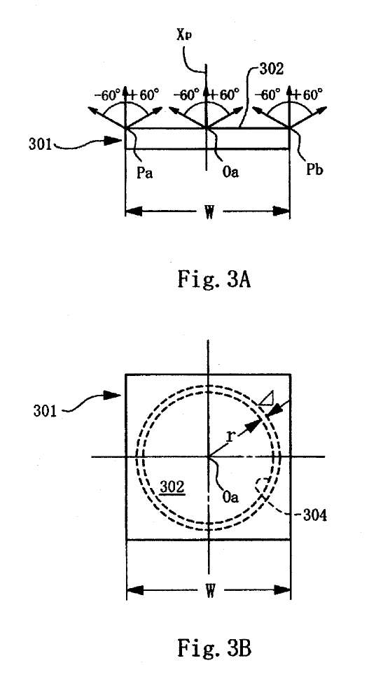

Concerning shapes of the collective lens which is located close vicinity to an emission surface of a light emitting diode, semispherical lenses with an incident surface covering the emission surface is popularly used. However, such a semispherical lens, in particular its curved surface, causes total reflection of part of light rays emerging from a periphery of the emission surface of the light emitting diode at emission angles within approximately ±60° and incident upon the incident surface of the semispherical lens and, in consequence, does not meet the requirement described in connection with FIGS. 3A and 3B that approximately 85% by quantity of light emerging from the light emitting diode within an emission angle range between approximately ±60° is efficiently utilized.

As a result of a study of the present invention made from diversified viewpoints by the inventors, it was revealed that a plano-convex lens having a semispherical surface prevents successfully its curved surface from causing total reflection of light rays from a light emitting diode when having a radius of convex ranging from 1 W to 1.5 W (W is a width of a quadrate emission surface of the light rays emitting diode or a diameter of a circle inscribed in the quadrate emission surface), an axial thickness of the plano-semispherical lens (a thickness between an apex and an plane surface of the plano-convex lens along the optical axis) less than the radius of curvature, and a total distance between the apex of the plano-convex lens and the emission surface of the light emitting diode not greater than the radius of convex where having an refractive index N>1.6. When configuring the emission surface of the light rays emitting diode and the plano-convex lens under these conditions, the collective lens system serves as a virtual imaging system.

In the case where the plano-convex lens has a radius of curvature approximately equal to 1.5 W and an axial thickness less than the radius of curvature and located in a relatively close position to the emission surface, it is enabled to cause light rays to exit from the convex surface of the plano-convex lens at an angle less than 35° with respect to the optical axis, as described by way of a first embodiment of the present invention provided below.

It is possible to employ a plano-convex lens having a radius of curvature approximately equal to 1 W if locating the plano-convex lens in an extremely close position to the emission surface. The light source device thus configured is possible to be incorporated as a small light source device in a specialized fiber optic illumination device which includes a light guide means comprising optical fiber bundle having a numerical aperture NA=0.87.

Nevertheless, when the plano-convex lens is minimized in the radius of curvature, for instance, approximately equal to 1 W, it is enabled to configure a fiber optic illumination device including a light guide means comprising an ordinary optical fiber bundle having a numerical aperture NA=0.57 which causes light rays to exit from a collective lens system at an angle less than 35° with respect to the optical axis by additionally incorporating a convex lens adjacent to the curved surface of a plano-convex lens located in close vicinity to the emission surface of a light emitting diode, as described by way of a second embodiment of the present invention provided below.

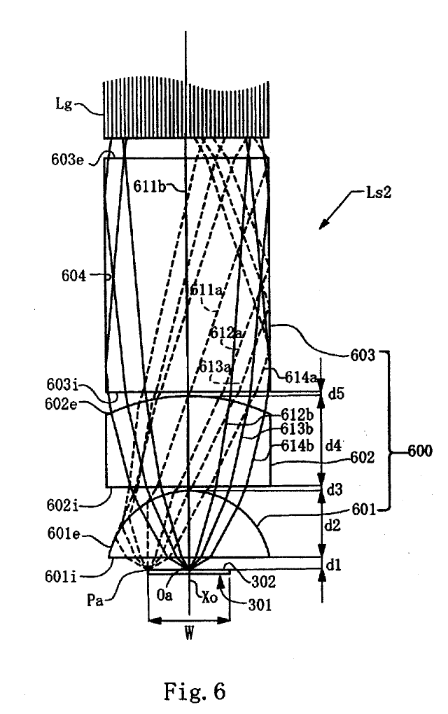

Referring to FIG. 5 showing a light source device Ls1 according to a preferred embodiment of the present invention, the light source device Ls1 comprises a light emitting diode 301 and a light collection optical means 500 coaxially aligned with the light emitting diode 301 along an optical axis Xo (which is in alignment with the principal axis Xp of the light emitting diode 301). In this embodiment, the light collection optical means 500 comprises a collective lens system which consists of a single plano-convex lens 501 having a positive power and a cylindrical reflection member 502, such as a solid cylindrical glass rod, having an internal reflection surface 503 coaxially aligned with each other along the optical axis Xo. Specifically, the light emitting diode 301 has an emission surface 302 shaped in a regular square having a width W=2 mm. The plano-convex lens 501, which is near semispherical in shape, has a refractive index n=1.768, a radius of curvature r1=∞ at an incident end surface 501i and a radius of curvature r2=2.8 mm at an exit end surface 501e, and an axial thickness (a thickness between an apex and the incident surface 501i along the optical axis Xo) d2=1.7 mm. The plano-convex lens 501 is placed at a space distance d1=0.8 mm from the light emitting diode 302 with the incident end surface 501i facing the emission surface 302. Denoted by a reference sign Lg is an optical fiber bundle used as a light guide means of a fiber optic illumination system known in the art. The optical fiber bundle Lg is located in face of and coaxial alignment with the light collection optical means 500. In FIG. 5, there are demonstratively shown emitted light rays 510a, 511a, 512a and 513a depicted by chained lines which emerge from a peripheral point Pa of the emission surface 302 at emission angles, for example 0°, ±30°, ±45° and ±60°, with respect to a light ray 510a in parallel to the optical axis Xo and emitted light rays 510b, 512b and 513b depicted by solid lines which emerge from a center point Oa of the emission surface 302 at emission angles, for example 0°, ±45° and ±60°,with respect to a light ray 510b in parallel with the optical axis Xo.

In order to capture light rays emerging from the peripheral point Pa of the emission surface 302 at an emission angle of −60° (i.e. outermost light ray), the plano-convex lens 501 is designed to have a radius r1 of the incident end surface 501i substantially determined depending upon the space distance dl between the light emitting diode 301 and the plano-convex lens 501. Specifically, when locating the plano-convex lens 501 at a space distance d1=0.8 mm from the light emitting diode 301 as shown in FIG. 5, the plano-convex lens 501 is given a radius of convex r2=2.8 mm at the exit end surface 501e.

The plano-convex lens 501 shown in FIG. 5 is located relative to the light emitting diode 301 so as to form a virtual image and designed to have a diameter large enough to sufficiently capture light rays emerging from the peripheral point Pa of the emission surface 302 at emission angles of ±60° and specified in terms of a refractive index, a radius of curvature and a thickness so as to prevent an occurrence of total reflection of light rays from the emission surface 302 defined by an inscribed circle.

The cylindrical reflection member 502 having an internal reflection surface 503 is made of a transparent material having a refractive index n=1.517 and has dimensions, specifically radii r3 and r4 of ∞ at incident and exit end surfaces 502i and 502e, respectively, a diameter of 4.7 mm which is substantially equal to the diameter of the plano-convex lens 501 and an axial thickness (a thickness between an apex and the incident surface 501i along the optical axis Xo) of 4.5 mm. The cylindrical reflection member 502 is arranged at a space distance d5 of 0.2 mm from the plano-convex lens 501 in coaxial alignment with the light emitting diode 301 and the plano-convex lens 501 so as to cause a total internal reflection by the internal reflection surface 503. The cylindrical reflection member 502 may be not always required to have a strictly specified diameter and may be modified in diameter according to mechanical structures in which the cylindrical reflection member 502 is installed. However, in order for the cylindrical reflection member 502 to sufficiently capture available light rays exiting from the plano-convex lens 501, the cylindrical reflection member 502 has an incident end surface 502i with a diameter desirably approximately equal to a diameter of the plano-convex lens 501. In this embodiment, light rays which the light emitting diode 301 emits at emission angles within ±60° with respect to the optical axis Xo exit from the cylindrical reflection member 502 at output angles within ±35° with respect to the optical axis Xo. Since this output angle is in accord with the acceptance angle (2θ=70°) of the light guide means, i.e. the optical fiber bundle Lg, which has a numerical aperture NA=0.57 and is placed in face of the exit end surface 502e of the cylindrical reflection member 502, the light guide means, i.e. the optical fiber bundle Lg, efficiently provides with emitted light from the light emitting diode 301.

Referring to FIG. 6 showing a light source device Ls2 according to an alternative embodiment of the present invention, the light source device Ls2 comprises a light emitting diode 301 shaped in a regular square and a light collection optical means 600 which comprises plano-convex first and second lenses 601 and 602, both having positive powers and coaxially aligned with each other along an optical axis Xo, and a cylindrical reflection member 603 having an internal reflection surface 604, such as a rigid cylinder made of a transparent material, in coaxial alignment with the light collection optical means 600. Denoted by a reference sign Lg is an optical fiber bundle used as a light guide means of a fiber optic illumination device known in the art. Specifically, the light emitting diode 301 has an emission surface 302 shaped in a regular square having a width W=2 mm. The plano-convex first lens 601 is nearly semispherical in shape and has a refractive index n=1.768, a radius of curvature r1=∞ at the incident end surface 601i and a radius of curvature r2=2 mm at the exit end surface 601e, and an axial thickness (a thickness between an apex and the incident surface 601i along the optical axis Xo) d2=1.6 mm. The plano-convex first lens 601 is designed to have a diameter as large as sufficiently capturing light rays emerging from the peripheral point Pa of the emission surface 302 at emissions angle within ±60° and is specified in terms of a refractive index, a radius of curvature and an axial thickness so that refraction of light rays incident thereupon at an angle of −60° is caused by the curved surface 601e without total internal reflection. The plano-convex first lens 601 is placed at a space distance d1=0.3 mm from the light emitting diode 301 with the incident end surface 601i facing the emission surface 302 of the light emitting diode 301. On the other hand, the plano-convex second lens 602 has a refractive index n=1.62, a radius of curvature r3=∞ at an incident end surface 602i and a radius of curvature r4=4.6 mm at an exit end surface 602e, and an axial thickness (a thickness between an apex and the incident surface 602i along the optical axis Xo) d4=2.2 mm. The plano-convex second lens 602 is placed at a space distance d3=0.1 mm from the plano-convex first lens 601 with the incident end surface 602i facing the plano-convex first lens 601. The cylindrical reflection member 603, which has an aperture similar in size to those of the plano-convex first and second lenses 601 and 602 and the internal reflection surface 604, has a refractive index n=1.62, radii of curvature r5 and r6=∞ at incident and exit end surfaces 603i and 603e, respectively, a diameter of 4 mm and an axial thickness of 5.7 mm. The cylindrical reflection member 603 is placed at a space distance d5 of 0.1 mm from and coaxially with the plano-convex second lens 602. The plano-convex second lens 602 performs the function of bringing a bundle of light rays exiting from the plano-convex first lens 601 into accord with a numerical aperture NA (0.57) of the optical fiber bundle Lg as the light guide means. As described above, it is important for the plano-convex second lens 602 to have a positive power smaller than the plano-convex first lens 601 in order to achieve the aim of slightly altering output angles of light rays exiting from the plano-convex first lens 601.

Since light rays 611a, 612a, 613a and 614a emerging from a peripheral point Pa of the emission surface 302 at emission angles of 0°, +30°, +45° and +60°, respectively, are refracted by and emerge from the plano-convex first lens 601 at output angles over 35° with respect to the optical axis Xo, the plano-convex second lens 602 is designed to alter output angles of these light rays less than 35° with respect to the optical axis Xo, so as thereby to bring the output angles into accord with a numerical aperture NA (0.57) of the optical fiber bundle Lg. At the same time, since the cylindrical reflection member 603 deflects light rays emerging from the plano-convex second lens 602 toward the optical axis Xo, so as thereby to collect effectively the light rays from the light emitting diode 301 onto the optical fiber bundle Lg as the light guide means.

On the other hand, as shown by solid lines in FIG. 6, light rays emerging from a center point Oa of the emission surface 302 travel passing through the plano-convex first and second lenses 601 and 602 and the cylindrical reflection member 603 and then reach the optical fiber bundle Lg. Specifically, light rays 611b, 612b, 613b and 614b take light paths which deviate apart from the optical axis Xo after emergence from the plano-convex second lens 602 and then change their light paths toward the optical axis Xo in the cylindrical reflection member 603 by virtue of total internal reflection. Therefore, the light collection optical means 600 is enabled to provide a desired centralization of collection of light at the exit end surface 603e by appropriately choosing dimensions thereof, e.g. diameter and thickness.

As is the case with the previous embodiment, the cylindrical reflection member 603 may be not always required to have a strictly specified diameter and allowed for dimensional alteration according to mechanical structures for installation. As long as the cylindrical reflection member 603 has at least the same diameter as the plano-convex second lens 602, light rays emerging from the plano-convex second lens 602 are made sufficiently available. As shown in FIG. 6 illustrating the cylindrical reflection member 603 having a thickness of 5.7 mm, a great part of light rays which the light emitting diode 301 emits from the peripheral point Pa of the emission surface 301 are directed toward the center of the optical fiber bundle Lg at the incident end, thereby falling within an acceptance angle (i.e. a numerical aperture NA) of the optical fiber bundle Lg.

The light source device Ls2 causes light rays from the light emitting diode 301 to fall within an aperture of the light guide member which is small as compared with that of the previous embodiment. In consequence, the light source device Ls2 can be utilized in a fiber optic illumination system including a small diameter of optical fiber bundle incorporated in endoscopes with an enhanced effect.

It is also to be understood that although the present invention has been described with regard to preferred embodiments thereof, various other embodiments and variants may occur to those skilled in the art, which are within the scope and spirit of the invention, and such other embodiments and variants are intended to be closed by the following claims.

What is claimed is:

1. A light source device for an illumination system having a light guide means, said light source device comprising:
a solid-state light emitting element capable of emitting its light from an emission surface which is shaped in quadrate and has a principal axis at an axial thereof;
a light collection lens system having a positive power which includes at least a plano-convex lens and is arranged coaxially with said solid-state light emitting element along said principal axis; and
a reflection member having a cylindrical reflection surface therein, said reflection member being arranged coaxially with side said solid-state light emitting element along said principal axis on a side opposite to said solid-state light emitting element with respect to said light collective lens system;
wherein said plano-convex lens is placed with a plane surface thereof directly facing and located at a space distance apart from said emission surface so as to form a virtual image of said emission surface.

2. The light source device as defined in claim 1, wherein said light collection lens system consists of a single plano-convex lens having a curved surface with a radius of curvature within a range between 1 and 1.5 times a width of said emission surface and an axial thickness smaller than said radius of curvature by more than said space distance, wherein said reflection member has an incident end surface with a diameter approximately equal to a diameter of said single plano-convex lens.

3. The light source device as defined in claim 1, wherein said light collection lens system consists of a plano-convex lens having a positive power and a convex lens which has a positive power smaller than said plano-convex lens and is arranged coaxially with and between said plano-convex lens and said reflection member.

4. The light source device as defined in claim 3, wherein said plano-convex lens has a curved surface with a radius of curvature within a range between 1 and 1.5 times a width of said emission surface and an axial thickness smaller than said radius of curvature by more than said space distance,
wherein said cylindrical reflection surface of said reflection member has a diameter approximately equal to a diameter of said plano-convex lens.
